(19) United States
(12) Patent Application Publication
(10) Pub. No.: US 2019/0182987 A1
(43) Pub. Date: Jun. 13, 2019

(54) RACK SYSTEM AND RACK DOOR THEREOF

(71) Applicant: AURAS Technology Co., Ltd., New Taipei City (TW)

(72) Inventors: CHIEN-AN CHEN, New Taipei City (TW); MU-SHU FAN, New Taipei City (TW); CHIEN-YU CHEN, New Taipei City (TW); WEI-HAO CHEN, New Taipei City (TW)

(21) Appl. No.: 16/217,178

(22) Filed: Dec. 12, 2018

Related U.S. Application Data
(60) Provisional application No. 62/598,141, filed on Dec. 13, 2017.

(30) Foreign Application Priority Data
Nov. 9, 2018 (TW) 107139898

(51) Int. Cl. H05K 7/20; H05K 7/18

(52) U.S. Cl. CPC H05K 7/20736; H05K 7/18; H05K 7/20172; H05K 7/20254; H05K 7/20272; H05K 7/20781

(57) ABSTRACT

A rack system includes a rack cabinet and a rack door. The rack door is selectively opened or closed relative to the rack cabinet. Moreover, plural electronic computing devices are installed within the rack cabinet. The rack door includes a heat dissipation device, a fan module and a door assembly. The heat dissipation device and the fan module are installed on the door assembly. At least one of the heat dissipation device and the fan module is detachable from the door assembly.

### CROSS-REFERENCE TO RELATED APPLICATION

This application claims priority to U.S. Provisional Patent Application No. 62/598,141 filed Dec. 13, 2017, the contents of which are incorporated herein by reference.

### FIELD OF THE INVENTION

The present invention relates to a field of heat dissipation, and more particularly to a rack system.

### BACKGROUND OF THE INVENTION

With the advancement and popularization of technology, various electronic computing devices have long been indispensable roles in people's daily lives. For example, the electronic computing devices are network storage devices, server devices, or the like. Generally, the electronic computing devices are stored in a rack cabinet that is made of cold-rolled steel or metal. Consequently, the electronic computing devices are protected by the rack cabinet, and the purpose of shielding the electromagnetic interference is achieved. In addition, the electronic computing devices are arranged in an orderly and neat manner. Moreover, the rack cabinet is closed by a door. After the door is opened, the electronic computing devices stored in the rack cabinet can be directly maintained and repaired by the user or the maintenance worker.

With the advent of big data and the Internet era, the processing capabilities of these electronic computer devices are increasing and the amount of the generated heat becomes larger and larger. Consequently, it is important to effectively dissipate the heat from the rack cabinet that stores the electronic computer devices. The heat dissipating efficiency directly influences the performance and the lives of the electronic computer devices. For increasing the heat dissipating efficiency, the door of the existing rack cabinet is equipped with a heat dissipation device that is not detachable or not easily detached. For example, the heat dissipation device is a condenser. The door is also referred as a door with a cooling kit. Due to the heat dissipation device, the ambient temperature of the rack cabinet is decreased. In addition, a fan installed in the rack cabinet or other place is employed to exhaust the waste heat from the rack cabinet. This technical is well known to those skilled in the art and will not be further described herein. Nowadays, the door with the combination of a condenser and a fan has not been disclosed.

On the other hand, since the rack cabinet is indispensable, the standard association or the industrial association has established a number of standards about the size, the material and the hole position of the rack cabinet for allowing the general manufacturers to follow. Therefore, it is important to integrate the components of the rack cabinet and its heat dissipation system on the basis of the existing standards while making effective use of the space and increasing the heat dissipating efficiency and the maintenance efficiency of various components.

### SUMMARY OF THE INVENTION

An object of the present invention provides a rack system with a rack cabinet and a rack door. A heat dissipation device installed in the rack door is detachable for facilitating check, maintenance and repair in the future.

In accordance with an aspect of the present invention, there is provided a rack system. The rack system includes a rack cabinet and a rack door. Moreover, at least one electronic computing device is installed within the rack cabinet. The rack door selectively opened or closed relative to the rack cabinet. The rack door includes a heat dissipation device, a fan module and a door frame assembly. The heat dissipation device is in fluid communication with the rack cabinet. A fluid medium flows through the heat dissipation device. The heat dissipation device exchanges heat with the fluid medium. The fan module is used for driving an airflow. The heat dissipation device and the fan module are installed on the door frame assembly. The heat dissipation device is a detachable heat dissipation device and/or the fan module is a detachable fan module.

In an embodiment, the door frame assembly includes an upper rim, a lower rim, a first lateral rim and a second lateral rim. An accommodation space is defined by the upper rim, the lower rim, the first lateral rim and the second lateral rim collaboratively. The fan module and the heat dissipation device are accommodated within the accommodation space.

In an embodiment, a spacing distance between the upper rim and the lower rim of the door frame assembly is smaller than a height of the rack cabinet.

In an embodiment, the heat dissipation device includes at least one casing coupling part, and the door frame assembly includes at least one first door frame coupling part. Each casing coupling part and the corresponding first door frame coupling part are coupled with each other, so that the heat dissipation device is fixed on the door frame assembly.

In an embodiment, each casing coupling part and the corresponding first door frame coupling part are coupled with each other in a screwing manner or a buckling manner.

In an embodiment, the fan module further includes a fan module edge frame, the fan module edge frame includes at least one fan module coupling part, and the door frame assembly further includes at least one second door frame coupling part. Each fan module coupling part and the corresponding second door frame coupling part are coupled with each other, so that the fan module is fixed on the door frame assembly.

In an embodiment, each fan module coupling part and the corresponding second door frame coupling part are coupled with each other in a screwing manner or a buckling manner.

In an embodiment, the fan module edge frame further includes at least one fan module auxiliary assembling part, and the door frame assembly further includes at least one lateral rim auxiliary assembling part, wherein the cooperation of each fan module auxiliary assembling part and the corresponding lateral rim auxiliary assembling part assists a user in assembling the fan module with the door frame assembly.

In an embodiment, each fan module auxiliary assembling part is a guiding groove with an opening, each lateral rim auxiliary assembling part is a bulge that is protruded toward an accommodation space of the door frame assembly, and the fan module is moved toward the accommodation space after each guiding groove is aligned with the corresponding bulge. Alternatively, each fan module auxiliary assembling part is a bulge, each lateral rim auxiliary assembling part is a guiding groove with an opening, and the fan module is moved toward the accommodation space after each bulge is aligned with the corresponding guiding groove.

In an embodiment, the fan module further includes at least one fan and a circuit board. The circuit board is electrically connected with a power source, and the at least one fan is connected with and powered by the circuit board.

In an embodiment, the fan is a detachable fan, each fan includes a fan connecting part, and the circuit board includes at least one fan module connecting part. Each fan connecting part and the corresponding fan module connecting part are electrically connected with each other, so that the corresponding fan is powered.

In an embodiment, the fan module further includes an intermediate frame assembly, and the intermediate frame assembly is connected with the fan module edge frame to define at least one fan receiving space. The at least one fan is received within the at least one fan receiving space.

In an embodiment, the intermediate frame assembly includes at least one intermediate frame coupling part, and each fan further includes at least one fan coupling part. Each fan coupling part and the corresponding intermediate frame coupling part are coupled with each other, so that the at least one fan is fixed on the fan module edge frame.

In an embodiment, each fan coupling part and the corresponding intermediate frame coupling part are coupled with each other in a screwing manner or a buckling manner.

In an embodiment, the circuit board is fixed on the fan module edge frame, or the fan connecting part and the fan module connecting part are respectively a male connector and a female connector, or the fan connecting part and the fan module connecting part are respectively a female connector and a male connector, or the at least one fan includes plural fans in an array arrangement.

In an embodiment, the rack door is directly connected with the rack cabinet, or the rack door is indirectly connected with the rack cabinet through a rack door adapting frame of the dock system.

In accordance with another aspect of the present invention, there is provided a rack door for a rack cabinet. Moreover, at least one electronic computing device is installed within the rack cabinet. The rack door is selectively opened or closed relative to the rack cabinet. The rack door includes a heat dissipation device, a fan module and a door frame assembly. The heat dissipation device is in fluid communication with the rack cabinet. A fluid medium flows through the heat dissipation device. The heat dissipation device exchanges heat with the fluid medium. The fan module is used for driving an airflow. The heat dissipation device and the fan module are installed on the door frame assembly. The heat dissipation device is a detachable heat dissipation device and/or the fan module is a detachable fan module.

In an embodiment, the door frame assembly includes an upper rim, a lower rim, a first lateral rim and a second lateral rim. An accommodation space is defined by the upper rim, the lower rim, the first lateral rim and the second lateral rim collaboratively. The fan module and the heat dissipation device are accommodated within the accommodation space.

In an embodiment, a spacing distance between the upper rim and the lower rim of the door frame assembly is smaller than a height of the rack cabinet.

In an embodiment, the heat dissipation device includes a casing and a fluid pipe. The fluid pipe is connected with the casing. The fluid medium is inputted into the heat dissipation device or outputted from the heat dissipation device through the fluid pipe.

In an embodiment, the casing includes at least one casing coupling part, and the door frame assembly includes at least one first door frame coupling part. Each casing coupling part and the corresponding first door frame coupling part are coupled with each other, so that the heat dissipation device is fixed on the door frame assembly.

In an embodiment, each casing coupling part and the corresponding first door frame coupling part are coupled with each other in a screwing manner or a buckling manner.

In an embodiment, the fan module further includes a fan module edge frame, the fan module edge frame includes at least one fan module coupling part, and the door frame assembly further includes at least one second door frame coupling part. Each fan module coupling part and the corresponding second door frame coupling part are coupled with each other, so that the fan module is fixed on the door frame assembly.

In an embodiment, each fan module coupling part and the corresponding second door frame coupling part are coupled with each other in a screwing manner or a buckling manner.

In an embodiment, the fan module edge frame further includes at least one fan module auxiliary assembling part, and the door frame assembly further includes at least one lateral rim auxiliary assembling part, wherein the cooperation of each fan module auxiliary assembling part and the corresponding lateral rim auxiliary assembling part assists a user in assembling the fan module with the door frame assembly.

In an embodiment, each fan module auxiliary assembling part is a guiding groove with an opening, each lateral rim auxiliary assembling part is a bulge that is protruded toward an accommodation space of the door frame assembly, and the fan module is moved toward the accommodation space after each guiding groove is aligned with the corresponding bulge. Alternatively, each fan module auxiliary assembling part is a bulge, each lateral rim auxiliary assembling part is a guiding groove with an opening, and the fan module is moved toward the accommodation space after each bulge is aligned with the corresponding guiding groove.

In an embodiment, the fan module further includes at least one fan and a circuit board. The circuit board is electrically connected with a power source, and the at least one fan is connected with and powered by the circuit board.

In an embodiment, the fan is a detachable fan, each fan includes a fan connecting part, and the circuit board includes at least one fan module connecting part. Each fan connecting part and the corresponding fan module connecting part are electrically connected with each other, so that the corresponding fan is powered.

In an embodiment, the fan module further includes an intermediate frame assembly, and the intermediate frame assembly is connected with the fan module edge frame to define at least one fan receiving space. The at least one fan is received within the at least one fan receiving space.

In an embodiment, the intermediate frame assembly includes at least one intermediate frame coupling part, and each fan further includes at least one fan coupling part. Each fan coupling part and the corresponding intermediate frame coupling part are coupled with each other, so that the at least one fan is fixed on the fan module edge frame.

In an embodiment, each fan coupling part and the corresponding intermediate frame coupling part are coupled with each other in a screwing manner or a buckling manner.

In an embodiment, the circuit board is fixed on the fan module edge frame, or the fan connecting part and the fan module connecting part are respectively a male connector and a female connector, or the fan connecting part and the fan module connecting part are respectively a female connector and a male connector, or the at least one fan includes plural fans in an array arrangement.

In an embodiment, the rack door is directly connected with the rack cabinet, or the rack door is indirectly connected with the rack cabinet through a rack door adapting frame.

The above objects and advantages of the present invention will become more readily apparent to those ordinarily skilled in the art after reviewing the following detailed description and accompanying drawings, in which:

### BRIEF DESCRIPTION OF THE DRAWINGS

FIG. 1 is a schematic view illustrating the structure concepts of a rack system according to a first embodiment of the present invention;

FIG. 2 is a schematic view illustrating the structure concepts of a rack door of the rack system as shown in FIG. 1 and taken along another viewpoint;

FIG. 3 is a schematic view illustrating the structure concepts of the rack door of the rack system as shown in FIG. 1, in which the heat dissipation device is detached from the rack door;

FIG. 4 is a schematic view illustrating the relationship between a door frame assembly and a fan module of the rack door of the rack system as shown in FIG. 1;

FIG. 5 is a schematic view illustrating the relationship between the door frame assembly and the fan module of the rack door of the rack system as shown in FIG. 1 and taken along another viewpoint;

FIG. 6 is a schematic perspective exploded view illustrating the fan module of the rack door of the rack system as shown in FIG. 1;

FIG. 7 is a schematic view illustrating the structure concepts of a rack system according to a second embodiment of the present invention; and

FIG. 8 is a schematic view illustrating the structure concepts of a rack door adapting frame of a rack door of the rack system as shown in FIG. 7.

### DETAILED DESCRIPTION OF THE PREFERRED EMBODIMENT

For illustration, the structures, organizations or components of the rack system and the rack door shown in the drawings of the present invention are in scale with the elements of the practical product. According to the requirements of descriptions, the components may be scaled up or scaled down in an unequal proportion. The implementations of the rack system and the rack door are not limited by the drawings.

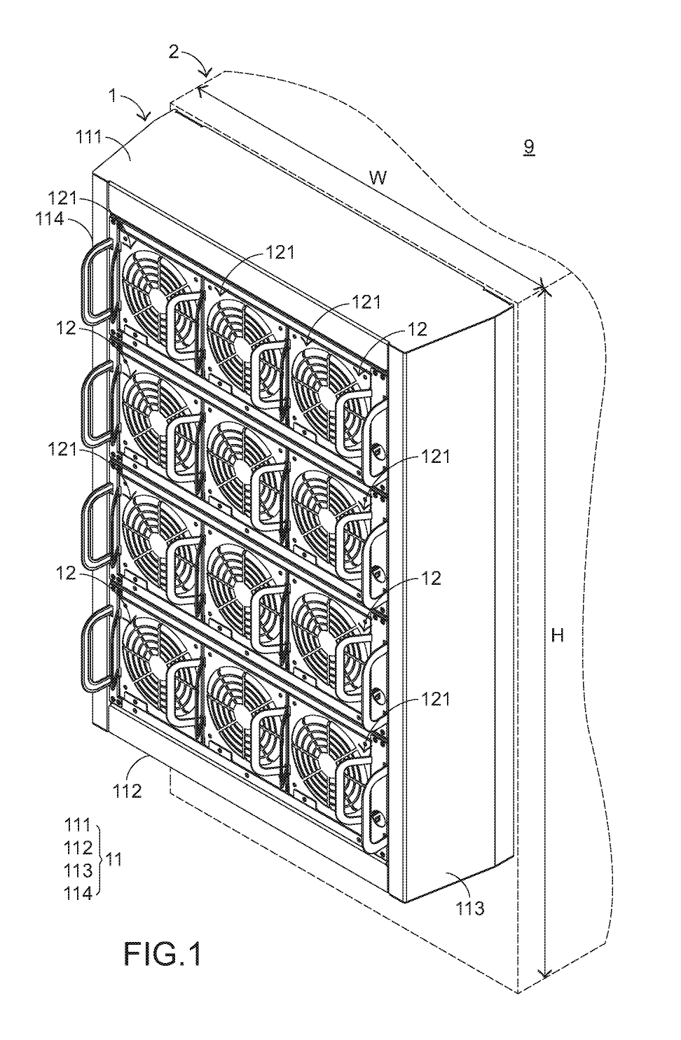

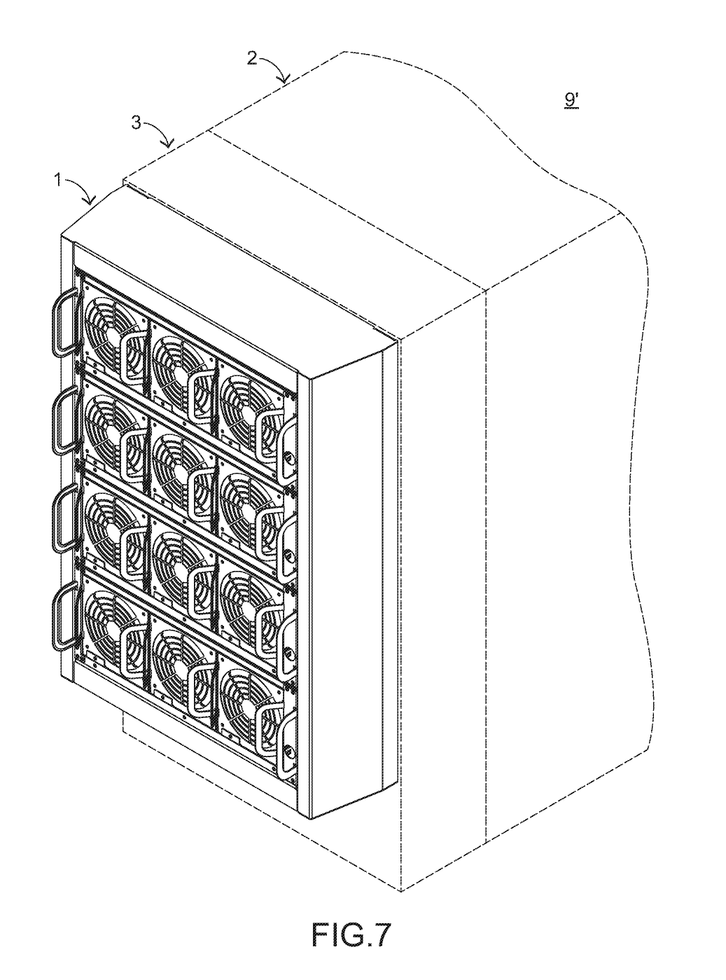

In this context, a rack cabinet is a single or combined cabinet that can be placed in a machine room to support plural electronic computing devices. In FIG. 1 and FIG. 7, the rack cabinet is exemplified by the dotted lines. Preferably but not exclusively, the electronic computing devices supported by the rack cabinet are network storage devices, server devices, or the like.

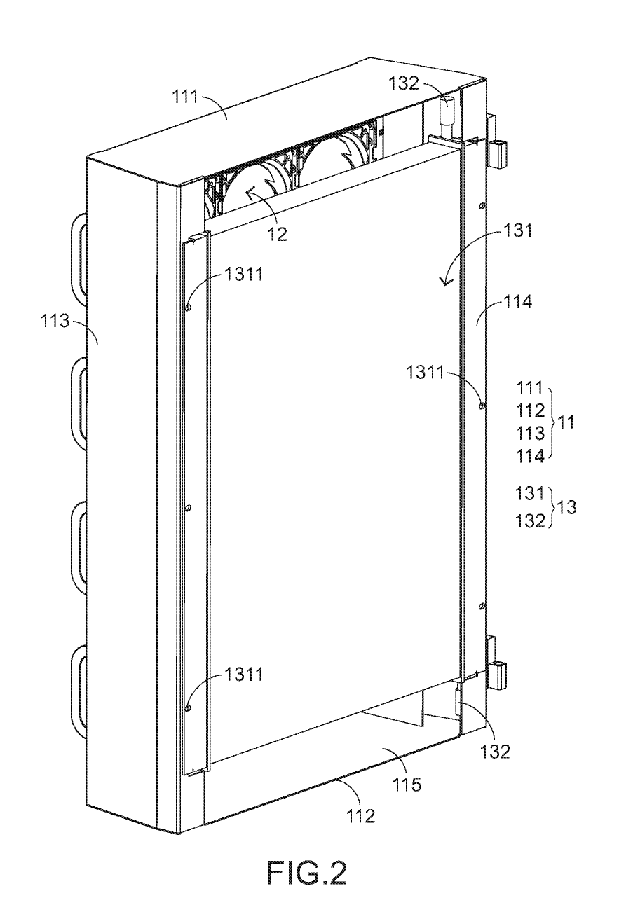

Please refer to FIG. 1 and FIG. 2. FIG. 1 is a schematic view illustrating the structure concepts of a rack system according to a first embodiment of the present invention. FIG. 2 is a schematic view illustrating the structure concepts of a rack door of the rack system as shown in FIG. 1 and taken along another viewpoint. The rack system 9 comprises a rack cabinet 2 and a rack door 1. The rack door 1 is directly or indirectly connected with the rack cabinet 2. Moreover, the rack door 1 is permitted to be opened or closed relative to the rack cabinet 2. After the rack door 1 is opened by the user or the maintenance worker, at least one electronic computing device (not shown) supported in the rack cabinet 2 can be maintained and repaired.

The rack door 1 comprises a door frame assembly 11, at least one fan module 12 and a heat dissipation device 13. The door frame assembly 11 comprises an upper rim 111, a lower rim 112, a first lateral rim 113 and a second lateral rim 114. An accommodation space 115 is defined by the upper rim 111, the lower rim 112, the first lateral rim 113 and the second lateral rim 114 collaboratively. The fan module 12 and the heat dissipation device 13 are accommodated within the accommodation space 115. The heat dissipation device 13 is in fluid communication with the rack cabinet 2. Consequently, the fluid medium can be circularly transferred through the heat dissipation device 13 and the rack cabinet 2. The fan module 12 and the heat dissipation device 13 are respectively a fan module and a detachable heat dissipation device that can be individually disassembled from the door frame assembly 11 or individually assembled with the door frame assembly 11.

The fan module 12 is used for driving the airflow to exhaust the hot air of the surroundings with the higher temperature. That is, the fan module 12 also provides the air cooling efficacy. Each fan module 12 comprises at least one fan 121. In this embodiment, the rack door 1 comprises four fan modules 12. Each fan module 12 comprises three fans 121. These fans 121 are detachable fans that are arranged in an array. However, the number of the fan modules 12 and the number and the arrangement of the fans 121 are not restricted. In this embodiment, the heat dissipation device 13 is a condenser. The condenser is one kind of heat exchanger. When the liquid medium flows through the condenser, the condenser performs heat exchange. According to the practical requirements, the condenser transforms the gas or vapor into a liquid. Moreover, the heat in the gas or vapor is quickly transferred to the nearby position of the heat dissipation device 13 and removed. Then, the heat in the air near the heat dissipation device 13 is dissipated away by the airflow that is driven by the fan module 12. According to the practical requirements, the condenser is used for decreasing the surrounding temperature. Consequently, the condenser and the airflow driven by the fan module 12 cooperate with each other to achieve the air cooling efficacy. It is noted that the example of the heat dissipation device 13 is not restricted.

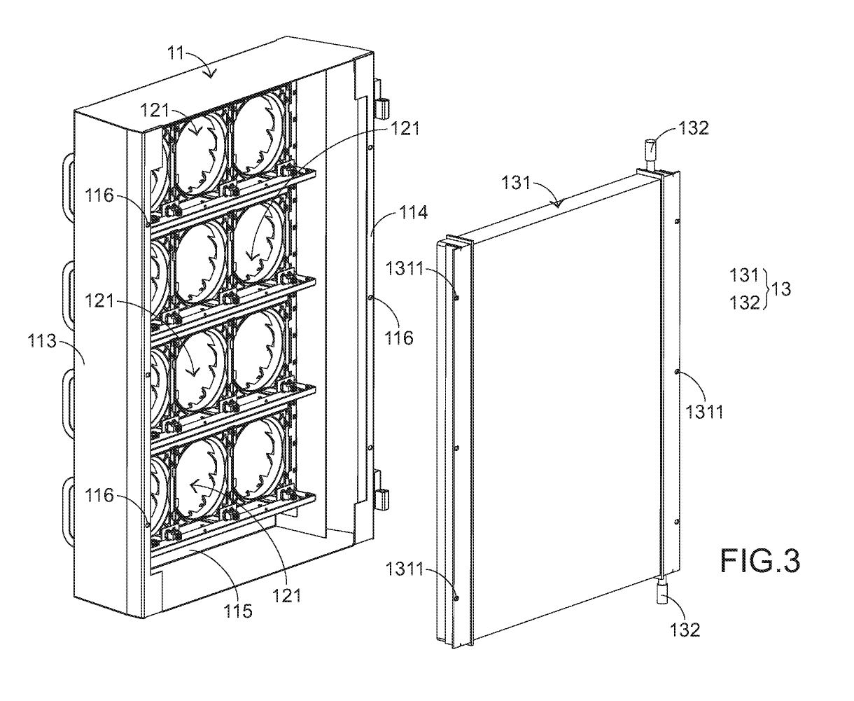

FIG. 3 is a schematic view illustrating the structure concepts of the rack door of the rack system as shown in FIG. 1, in which the heat dissipation device is detached from the rack door. The heat dissipation device 13 comprises a casing 131 and a fluid pipe 132. The fluid pipe 132 is connected with the casing 131. The fluid medium is inputted into the heat dissipation device 13 or outputted from the heat dissipation device 13 through the fluid pipe 132. The casing 131 comprises at least one casing coupling part 1311. The door frame assembly 11 comprises at least one first door frame coupling part 116. After each casing coupling part 1311 and the corresponding first door frame coupling part 116 are coupled with each other, the heat dissipation device 13 is fixed on the door frame assembly 11.

In this embodiment, each first door frame coupling part 116 of the door frame assembly 11 is located at the front side of the first lateral rim 113 of the door frame assembly 11 or located at the front side of the second lateral rim 114 of the door frame assembly 11. Each casing coupling part 1311 of the heat dissipation device 13 and the corresponding first door frame coupling part 116 are coupled with each other in a screwing manner. The position of the first door frame coupling part 116 and the way of coupling the first door frame coupling part 116 with the casing coupling part 1311 of the heat dissipation device 13 are not restricted. It is noted that numerous modifications and alterations may be made while retaining the teachings of the invention. For example, in another embodiment, each casing coupling part 1311 of the heat dissipation device 13 and the corresponding first door frame coupling part 116 are coupled with each other in a buckling manner.

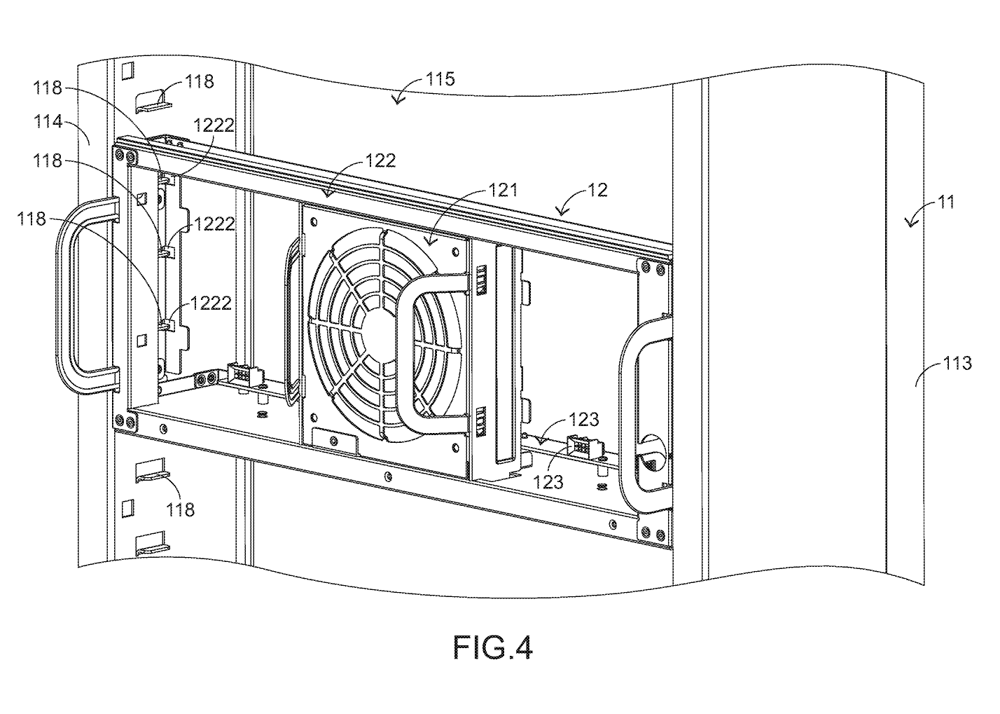

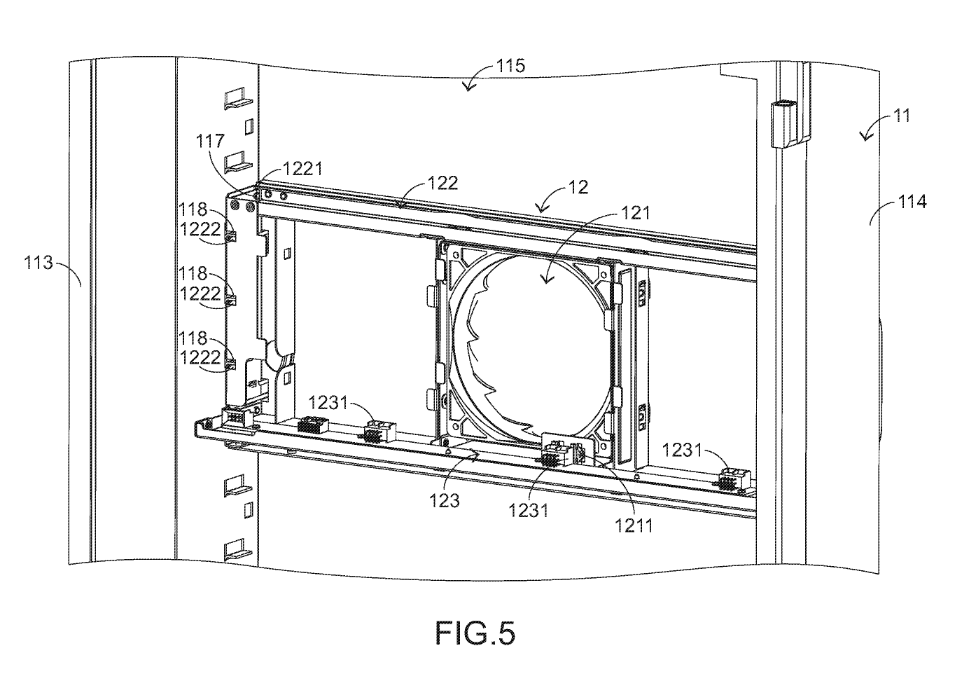

Please refer to FIG. 4 and FIG. 5. FIG. 4 is a schematic view illustrating the relationship between a door frame assembly and a fan module of the rack door of the rack system as shown in FIG. 1. FIG. 5 is a schematic view illustrating the relationship between the door frame assembly and the fan module of the rack door of the rack system as shown in FIG. 1 and taken along another viewpoint. For succinctness, only one fan module 12 and one fan 121 are shown in FIG. 4 and FIG. 5. As shown in FIG. 4 and FIG. 5, the user or the maintenance worker may disassemble the fan module 12 from the door frame assembly 11 or assemble the fan module 12 with the door frame assembly 11.

Moreover, each fan module 12 further comprises a fan module edge frame 122. The fan module edge frame 122 comprises at least one fan module coupling part 1221. The door frame assembly 11 further comprises at least one second door frame coupling part 117 corresponding to the at least one fan module coupling part 1221. After each fan module coupling part 1221 and the corresponding second door frame coupling part 117 are coupled with each other, the fan module 12 is fixed on the door frame assembly 11.

In this embodiment, each second door frame coupling part 117 of the door frame assembly 11 is located at an inner wall of the first lateral rim 113 of the door frame assembly 11 or an inner wall of the second lateral rim 114 of the of the door frame assembly 11. Each fan module coupling part 1221 and the corresponding second door frame coupling part 117 are coupled with each other in a screwing manner. The position of the second door frame coupling part 117 and the way of coupling the second door frame coupling part 117 with the fan module coupling part 1221 are not restricted. It is noted that numerous modifications and alterations may be made while retaining the teachings of the invention. For example, in another embodiment, each fan module coupling part 1221 and the corresponding second door frame coupling part 117 are coupled with each other in a buckling manner.

Preferably but not exclusively, the fan module edge frame 122 of each fan module 12 further comprises at least one fan module auxiliary assembling part 1222. At least one of the first lateral rim 113 and the second lateral rim 114 of the door frame assembly 11 further comprises at least one lateral rim auxiliary assembling part 118 corresponding to the at least one fan module auxiliary assembling part 1222. The cooperation of the at least one fan module auxiliary assembling part 1222 and the corresponding lateral rim auxiliary assembling part 118 can assist the user in assembling the fan module 12 with the door frame assembly 11.

In this embodiment, each fan module auxiliary assembling part 1222 is a guiding groove with an opening, and each lateral rim auxiliary assembling part 118 is a plate-shaped bulge that is protruded toward the accommodation space 115 of the door frame assembly 11. During the process of assembling the fan module 12 with the door frame assembly 11, the user or the maintenance worker may align the opening of the guiding groove with the suitable bulge according to the practical position and then push the fan module 12 toward the accommodation space 115 of the door frame assembly 11. Consequently, this design can assist the user or the maintenance worker in positioning the fan module 12. After the fan module 12 is positioned, the user or the maintenance worker may fix the fan module 12 on the door frame assembly 11 through the fan module coupling part 1221 and the corresponding second door frame coupling part 117.

However, the examples of the fan module auxiliary assembling part 1222 and the lateral rim auxiliary assembling part 118 are not restricted. It is noted that numerous modifications and alterations may be made while retaining the teachings of the invention. For example, in another embodiment, the fan module auxiliary assembling part 1222 is a bulge, and each lateral rim auxiliary assembling part 118 is a guiding groove with an opening. During the process of assembling the fan module 12 with the door frame assembly 11, the user or the maintenance worker may align the bulge with the suitable guiding groove according to the practical position and then push the fan module 12 toward the accommodation space 115 of the door frame assembly 11. Consequently, this design can assist the user or the maintenance worker in positioning the fan module 12.

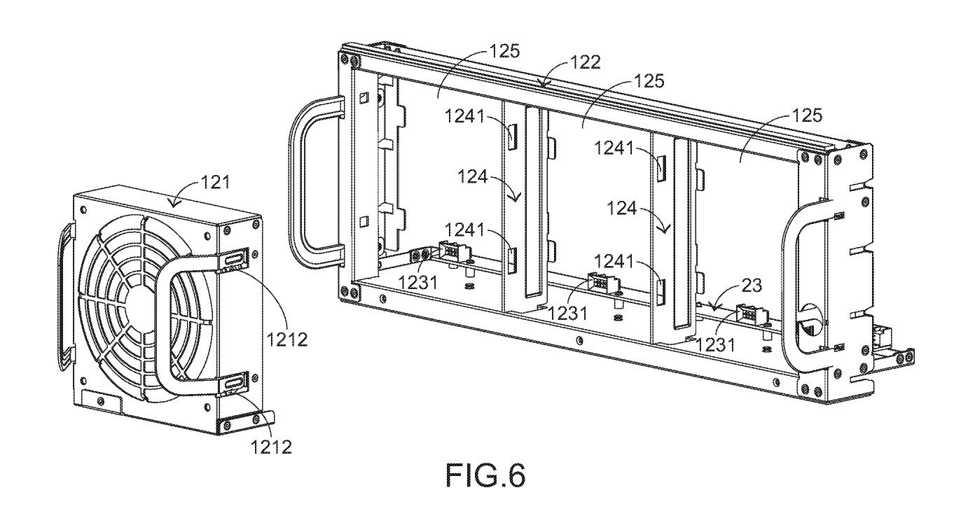

FIG. 6 is a schematic perspective exploded view illustrating the fan module of the rack door of the rack system as shown in FIG. 1. For succinctness, only one fan 121 is shown in FIG. 6. As shown in FIG. 6, the user or the maintenance worker may disassemble the fan 121 from the fan module edge frame 122 or assemble the fan 121 with the fan module edge frame 122.

Moreover, each fan module 12 further comprises a circuit board 123. The circuit board 123 is electrically connected with a power source (not shown) directly or indirectly. The fan module 12 further comprises at least one fan module connecting part 1231 corresponding to the at least one fan 121. Each fan 121 comprises a fan connecting part 1211 (see FIG. 5). When the fan 121 is assembled with the fan module 12 by the user or the maintenance worker, the fan connecting part 1211 of the fan 121 and the fan module connecting part 1231 of the fan module 12 are electrically connected with each other. Consequently, the fan 121 is powered and operated.

In this embodiment, the circuit board 123 of the fan module 12 is fixed on the fan module edge frame 122. In addition, the fan module connecting part 1231 is a female connector, and the fan connecting part 1211 is a male connector. Consequently, the process of disassembling the fan 121 from the fan module edge frame 122 or the process of assembling the fan 121 with the fan module edge frame 122 can be easily performed by the user or the maintenance worker in a hot-swappable manner. However, the installation position of the circuit board 123 of the fan module 12, the example of the fan module connecting part 1231 and the example of the fan connecting part 1211 are not restricted and can be modified by those skilled in the art according to the practical requirements. For example, in another embodiment, the fan module connecting part 1231 is a male connector, and the fan connecting part 1211 is a female connector.

Preferably but not exclusively, the fan module 12 further comprises an intermediate frame assembly 124. The intermediate frame assembly 124 is connected with the fan module edge frame 122. Consequently, at least one fan receiving space 125 for receiving the at least one fan 121 is defined. The intermediate frame assembly 124 comprises at least one intermediate frame coupling part 1241. Each fan 121 further comprises at least one fan coupling part 1212 corresponding to the at least one intermediate frame coupling part 1241. After the fan coupling part 1212 is coupled with the corresponding intermediate frame coupling part 1241, the fan 121 is fixed on the fan module edge frame 122.

In this embodiment, each fan coupling part 1212 is coupled with the corresponding intermediate frame coupling part 1241 in a buckling manner. The way of coupling the fan coupling part 1212 with the corresponding intermediate frame coupling part 1241 is not restricted. For example, in another embodiment, each fan coupling part 1212 is coupled with the corresponding intermediate frame coupling part 1241 in a screwing manner or any other appropriate manner. It is noted that numerous modifications and alterations may be made while retaining the teachings of the invention.

Please refer to FIG. 1 again. The length and the width of the rack door 1 are not restrictedly identical to the height H and the width W of the rack cabinet 2. In this embodiment, the spacing distance between the first lateral rim 113 and the second lateral rim 114 of the door frame assembly 11 is appropriately equal to the width W of the rack cabinet 2. However, the spacing distance between the upper rim 111 and the lower rim 112 of the door frame assembly 11 is smaller than the height H of the rack cabinet 2. An underlying space of the rack door 1 is aligned with a specified part (not shown) of the rack cabinet 2. Consequently, the user or the maintenance worker can directly check, maintain or repair the specified part without the need of opening the rack door 1.

In an embodiment, the specified part is a coolant distribution unit (CDU). The coolant distribution unit is a water-cooling component for directly transferring the fluid medium (e.g., the cooling liquid) to plural cold plates (not shown) corresponding to plural electronic computing devices through plural pipes (not shown) simultaneously and adjusting the flowrate. This technical is well known to those skilled in the art and will not be further described herein. The example of the specified part is presented herein for purpose of illustration and description only. That is, the specified part that is installed in the rack cabinet 2 and aligned with the underlying space of the rack door 1 is not limited to the coolant distribution unit.

It is noted that the length and the width of the rack door 1 and the position relationship between the rack door 1 and the rack cabinet 2 are not restricted. For example, in another embodiment, the length and the width of the rack door 1 are identical to the height H and the width W of the rack cabinet 2 according to the practical requirements. It is noted that numerous modifications and alterations may be made while retaining the teachings of the invention. For example, in another embodiment, a specified position of the rack cabinet 2 is not aligned with the rack door 1.

FIG. 7 is a schematic view illustrating the structure concepts of a rack system according to a second embodiment of the present invention. The components of the rack system 9′ of this embodiment that are similar to those of the first embodiment are not redundantly described herein. In comparison with the first embodiment, the dock system 9′ further comprises a rack door adapting frame 3. The rack door adapting frame 3 is arranged between the rack door 1 and the rack cabinet 2. The rack door 1 and the rack cabinet 2 are connected with each other through the rack door adapting frame 3. In FIG. 7, the rack door adapting frame 3 is exemplified by the dotted lines.

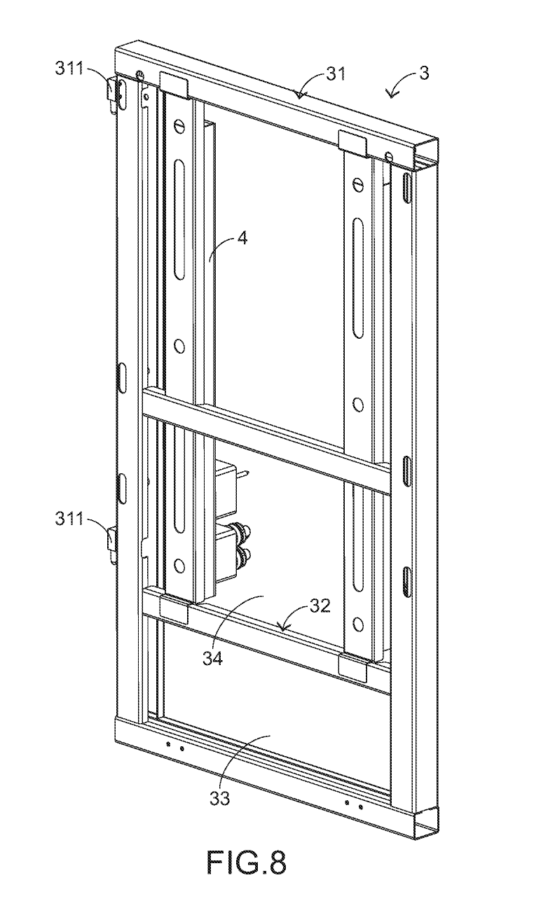

FIG. 8 is a schematic view illustrating the structure concepts of a rack door adapting frame of the rack system as shown in FIG. 7. The viewpoint of FIG. 8 is taken in the direction from the rack door 1 (not shown in FIG. 8) to the rack cabinet 2 (not shown in FIG. 8). The rack door adapting frame 3 comprises an edge adapting assembly 31 and an intermediate adapting assembly 32. The edge adapting assembly 31 is the main body of the rack door adapting frame 3 to define the length and the width of the rack door adapting frame 3. In addition, the length and the width of the rack door adapting frame 3 are substantially equal to the length and the width of the rack cabinet 2. Moreover, the edge adapting assembly 31 comprises one or more joining parts 311. The rack cabinet 2 and the rack door 1 are combined together through the joining parts 311.

In this embodiment, each joining part 311 is disposed on a lateral rim of the edge adapting assembly 31, and the joining part 311 is connected with both of the rack cabinet 2 and the rack door 1. It is noted that the position and the type of the joining part 311 are not restricted. For example, through the joining part 311, the rack door adapting frame 3 is connected with the rack door adapting frame 3 only or connected with the rack door 1 only.

In this embodiment, the edge adapting assembly 31 is also used for fixing or connecting the intermediate adapting assembly 32. The intermediate adapting assembly 32 comprises one or more linear bars, wherein the linear bar is optionally equipped with a partial bent structure. The intermediate adapting assembly 32 is fixed or connected between the upper rim and the lower rim of the edge adapting assembly 31, or the intermediate adapting assembly 32 is fixed or connected between the two lateral rims of the edge adapting assembly 31. Moreover, different spaces are defined by the intermediate adapting assembly 32 within the scope of the edge adapting assembly 31 for providing different use purposes.

In this embodiment, an adapting space 33 is defined by the intermediate adapting assembly 32. The adapting space 33 is aligned with the underlying space of the rack door 1 and the specified part of the rack cabinet 2. Consequently, the user or the maintenance worker can directly check, maintain or repair the specified part from the outside. In an embodiment, the specified part is a coolant distribution unit (CDU), but is not limited thereto. Moreover, another adapting space 34 is provided for installing other parts. For example, a fluid piping system 4 is installed in the adapting space 34. The fluid medium for use in liquid-cooling heat dissipation is transferred through the fluid piping system 4. Moreover, the intermediate adapting assembly 32 further comprises guiding rails, coupling holes or any other appropriate fixing or connecting mechanism.

From the above descriptions, the heat dissipation device 13 and the fan module 12 of the rack door 1 of the rack system 9 or 9′ can be individually disassembled from the door frame assembly 11 or assembled with the door frame assembly 11. Moreover, the fan 121 can be individually disassembled from the fan module edge frame 122 or assembled with the fan module edge frame 122. In case that one of the heat dissipation device 13, the fan module 12 and the fan 121 is damaged or abnormally operated, the user or the maintenance worker may remove the damaged or abnormal one of the heat dissipation device 13, the fan module 12 and the fan 121 from the rack door 1 without the need of disassembling rack door 1 from the rack cabinet 2. That is, the damaged or abnormal component can be maintained and repaired. Under this circumstance, the maintenance and repair efficacy is enhanced. Moreover, since the fan module 12 and the heat dissipation device 13 are integrated into the rack door 1, these components do not occupy the installation space.

In the above embodiments, the heat dissipation device, the fan module of the rack door of the rack system and the fan of the fan module are detachable. It is noted that numerous modifications and alterations may be made while retaining the teachings of the invention. For example, in another embodiment, only the heat dissipation device is detachable. The fan module and the fan of the fan module are not detachable. In a further embodiment, the heat dissipation device is not detachable, but the fan module and the fan of the fan module are detachable. Alternatively, the heat dissipation device and the fan of the fan module are not detachable, but only the fan module is detachable.

While the invention has been described in terms of what is presently considered to be the most practical and preferred embodiments, it is to be understood that the invention needs not be limited to the disclosed embodiments. On the contrary, it is intended to cover various modifications and similar arrangements included within the spirit and scope of the appended claims which are to be accorded with the broadest interpretation so as to encompass all modifications and similar structures.

What is claimed is:

1. A rack system, comprising:
a rack cabinet, wherein at least one electronic computing device is installed within the rack cabinet; and
a rack door selectively opened or closed relative to the rack cabinet, and comprising:
a heat dissipation device in fluid communication with the rack cabinet, wherein a fluid medium flows through the heat dissipation device, and the heat dissipation device exchanges heat with the fluid medium;
a fan module for driving an airflow; and
a door frame assembly, wherein the heat dissipation device and the fan module are installed on the door frame assembly,
wherein the heat dissipation device is a detachable heat dissipation device and/or the fan module is a detachable fan module.

2. The rack system according to claim 1, wherein the door frame assembly comprises an upper rim, a lower rim, a first lateral rim and a second lateral rim, wherein an accommodation space is defined by the upper rim, the lower rim, the first lateral rim and the second lateral rim collaboratively, and the fan module and the heat dissipation device are accommodated within the accommodation space.

3. The rack system according to claim 2, wherein a spacing distance between the upper rim and the lower rim of the door frame assembly is smaller than a height of the rack cabinet.

4. The rack system according to claim 1, wherein the heat dissipation device comprises at least one casing coupling part, and the door frame assembly comprises at least one first door frame coupling part, wherein each casing coupling part and the corresponding first door frame coupling part are coupled with each other, so that the heat dissipation device is fixed on the door frame assembly.

5. The rack system according to claim 4, wherein each casing coupling part and the corresponding first door frame coupling part are coupled with each other in a screwing manner or a buckling manner.

6. The rack system according to claim 1, wherein the fan module further comprises a fan module edge frame, the fan module edge frame comprises at least one fan module coupling part, and the door frame assembly further comprises at least one second door frame coupling part, wherein each fan module coupling part and the corresponding second door frame coupling part are coupled with each other, so that the fan module is fixed on the door frame assembly.

7. The rack system according to claim 6, wherein each fan module coupling part and the corresponding second door frame coupling part are coupled with each other in a screwing manner or a buckling manner.

8. The rack system according to claim 6, wherein the fan module edge frame further comprises at least one fan module auxiliary assembling part, and the door frame assembly further comprises at least one lateral rim auxiliary assembling part, wherein the cooperation of each fan module auxiliary assembling part and the corresponding lateral rim auxiliary assembling part assists a user in assembling the fan module with the door frame assembly.

9. The rack system according to claim 8, wherein each fan module auxiliary assembling part is a guiding groove with an opening, each lateral rim auxiliary assembling part is a bulge that is protruded toward an accommodation space of the door frame assembly, and the fan module is moved toward the accommodation space after each guiding groove is aligned with the corresponding bulge, or wherein each fan module auxiliary assembling part is a bulge, each lateral rim auxiliary assembling part is a guiding groove with an opening, and the fan module is moved toward the accommodation space after each bulge is aligned with the corresponding guiding groove.

10. The rack system according to claim 6, wherein the fan module further comprises at least one fan and a circuit board, wherein the circuit board is electrically connected with a power source, and the at least one fan is connected with and powered by the circuit board.

11. The rack system according to claim 10, wherein the fan is a detachable fan, each fan comprises a fan connecting part, and the circuit board comprises at least one fan module connecting part, wherein each fan connecting part and the corresponding fan module connecting part are electrically connected with each other, so that the corresponding fan is powered.

12. The rack system according to claim 11, wherein the fan module further comprises an intermediate frame assembly, and the intermediate frame assembly is connected with the fan module edge frame to define at least one fan receiving space, wherein the at least one fan is received within the at least one fan receiving space.

13. The rack system according to claim 12, wherein the intermediate frame assembly comprises at least one intermediate frame coupling part, and each fan further comprises at least one fan coupling part, wherein each fan coupling part and the corresponding intermediate frame coupling part are coupled with each other, so that the at least one fan is fixed on the fan module edge frame.

14. The rack system according to claim 13, wherein each fan coupling part and the corresponding intermediate frame coupling part are coupled with each other in a screwing manner or a buckling manner.

15. The rack system according to claim 11, wherein the circuit board is fixed on the fan module edge frame, or the fan connecting part and the fan module connecting part are respectively a male connector and a female connector, or the fan connecting part and the fan module connecting part are respectively a female connector and a male connector, or the at least one fan comprises plural fans in an array arrangement.

16. The rack system according to claim 1, wherein the rack door is directly connected with the rack cabinet, or the rack door is indirectly connected with the rack cabinet through a rack door adapting frame of the dock system.

17. A rack door for a rack cabinet, at least one electronic computing device being installed within the rack cabinet, the rack door being selectively opened or closed relative to the rack cabinet, the rack door comprising:
a heat dissipation device in fluid communication with the rack cabinet, wherein a fluid medium flows through the heat dissipation device, and the heat dissipation device exchanges heat with the fluid medium;
a fan module for driving an airflow; and
a door frame assembly, wherein the heat dissipation device and the fan module are installed on the door frame assembly,
wherein the heat dissipation device is a detachable heat dissipation device and/or the fan module is a detachable fan module.

18. The rack door according to claim 17, wherein the door frame assembly comprises an upper rim, a lower rim, a first lateral rim and a second lateral rim, wherein an accommodation space is defined by the upper rim, the lower rim, the first lateral rim and the second lateral rim collaboratively, and the fan module and the heat dissipation device are accommodated within the accommodation space.

19. The rack door according to claim 18, wherein a spacing distance between the upper rim and the lower rim of the door frame assembly is smaller than a height of the rack cabinet.

20. The rack door according to claim 17, wherein the heat dissipation device comprises a casing and a fluid pipe, wherein the fluid pipe is connected with the casing, and the fluid medium is inputted into the heat dissipation device or outputted from the heat dissipation device through the fluid pipe.

21. The rack door according to claim 20, wherein the casing comprises at least one casing coupling part, and the door frame assembly comprises at least one first door frame coupling part, wherein each casing coupling part and the corresponding first door frame coupling part are coupled with each other, so that the heat dissipation device is fixed on the door frame assembly.

22. The rack door according to claim 21, wherein each casing coupling part and the corresponding first door frame coupling part are coupled with each other in a screwing manner or a buckling manner.

23. The rack door according to claim 17, wherein the fan module further comprises a fan module edge frame, the fan module edge frame comprises at least one fan module coupling part, and the door frame assembly further comprises at least one second door frame coupling part, wherein each fan module coupling part and the corresponding second door frame coupling part are coupled with each other, so that the fan module is fixed on the door frame assembly.

24. The rack door according to claim 23, wherein each fan module coupling part and the corresponding second door frame coupling part are coupled with each other in a screwing manner or a buckling manner.

25. The rack door according to claim 23, wherein the fan module edge frame further comprises at least one fan module auxiliary assembling part, and the door frame assembly further comprises at least one lateral rim auxiliary assembling part, wherein the cooperation of each fan module auxiliary assembling part and the corresponding lateral rim auxiliary assembling part assists a user in assembling the fan module with the door frame assembly.

26. The rack door according to claim 25, wherein each fan module auxiliary assembling part is a guiding groove with an opening, each lateral rim auxiliary assembling part is a bulge that is protruded toward an accommodation space of the door frame assembly, and the fan module is moved toward the accommodation space after each guiding groove is aligned with the corresponding bulge, or wherein each fan module auxiliary assembling part is a bulge, each lateral rim auxiliary assembling part is a guiding groove with an opening, and the fan module is moved toward the accommodation space after each bulge is aligned with the corresponding guiding groove.

27. The rack door according to claim 23, wherein the fan module further comprises at least one fan and a circuit board, wherein the circuit board is electrically connected with a power source, and the at least one fan is connected with and powered by the circuit board.

28. The rack door according to claim 27, wherein the fan is a detachable fan, each fan comprises a fan connecting part, and the circuit board comprises at least one fan module connecting part, wherein each fan connecting part and the corresponding fan module connecting part are electrically connected with each other, so that the corresponding fan is powered.

29. The rack door according to claim 28, wherein the fan module further comprises an intermediate frame assembly, and the intermediate frame assembly is connected with the fan module edge frame to define at least one fan receiving space, wherein the at least one fan is received within the at least one fan receiving space.

30. The rack door according to claim 29, wherein the intermediate frame assembly comprises at least one intermediate frame coupling part, and each fan further comprises at least one fan coupling part, wherein each fan coupling part and the corresponding intermediate frame coupling part are coupled with each other, so that the at least one fan is fixed on the fan module edge frame.

31. The rack door according to claim 30, wherein each fan coupling part and the corresponding intermediate frame coupling part are coupled with each other in a screwing manner or a buckling manner.

32. The rack door according to claim 28, wherein the circuit board is fixed on the fan module edge frame, or the fan connecting part and the fan module connecting part are respectively a male connector and a female connector, or the fan connecting part and the fan module connecting part are respectively a female connector and a male connector, or the at least one fan comprises plural fans in an array arrangement.

33. The rack door according to claim 17, wherein the rack door is directly connected with the rack cabinet, or the rack door is indirectly connected with the rack cabinet through a rack door adapting frame.
